(19) United States
(12) Patent Application Publication
(10) Pub. No.: US 2014/0093373 A1
(43) Pub. Date: Apr. 3, 2014

(54) SYSTEM AND METHOD FOR DETECTING LIGHTNING STRIKES ON A WIND TURBINE

(71) Applicant: GENERAL ELECTRIC COMPANY, Schenectady, NY (US)

(72) Inventors: Michael Schmidt, Boston, MA (US); Michael Christopher Booth, Simpsonville, SC (US)

(73) Assignee: GENERAL ELECTRIC COMPANY, Schenectady, NY (US)

(21) Appl. No.: 13/633,987

(22) Filed: Oct. 3, 2012

(51) Int. Cl. G01R 31/02; F03D 11/00

(52) U.S. Cl. 416/61; 324/72

(57) ABSTRACT

A system and associated method for detecting lighting strikes on a wind turbine uses a plurality of lightning strike conductors that are connected to any combination of the wind turbine components. A common ground cable is connected to the conductors and to a wind turbine grounding system. A sensor is operatively configured on the common ground cable to detect current flowing through the cable from a lightning strike incident on any one of the receptors, with the sensor producing a signal proportional to the intensity of the lightning strike.

### FIELD OF THE INVENTION

The present disclosure relates in general to wind turbines, and more particularly to systems and methods for detecting lightning strikes on wind turbines.

### BACKGROUND OF THE INVENTION

Because of their relatively tall height, wind turbines are susceptible to lightning strikes. Lightning rods and similar devices may provide a certain protections against lightning strikes, but a powerful strike can still damage many components associated with the wind turbine. High currents may be conducted to or from ground through the wind turbine along various paths and entry/exit points that can depend on complex ionization conditions, potentials, cloud positions, etc. Therefore, various forms of damage can result depending on the intensity, entry/exit position, and current conduction path. For example, lightning strikes can destroy electronic components and delaminate wind turbine blade materials, which can create unsafe operating conditions or failure of the turbine.

Wind farm owners often face the situation of not knowing when or if a wind turbine has actually been struck by lightning. This leads to a turbine that may be damaged from a strike continuing to operate, causing further damage to the wind turbine. The wind turbine blades are particularly susceptible to damage from lightning strikes. A strike may cause a small crack or defect (e.g., delamination) in the blade, which can grow and lead to complete blade failure if not detected and repaired. In addition, wind turbine manufacturers often guarantee their blades against lighting strikes up to a certain strike intensity, which requires expensive systems and means for measuring lightning strike intensities.

A need thus remains for improved systems, methods, and apparatus for detecting and assessing damage from lightning strikes on wind turbines.

### BRIEF DESCRIPTION OF THE INVENTION

Aspects and advantages of the invention will be set forth in part in the following description, or may be obvious from the description, or may be learned through practice of the invention.

In particular embodiments, a wind turbine is configured with a lightning strike detection system. The wind turbine generally includes a tower mounted on a ground-level foundation. A hub is mounted atop the tower and turbine blades are configured on the hub. A plurality of lightning strike conductors are connected to any combination of the blades and hub to conduct lightning strikes to ground. These conductors may, in a certain embodiment, be connected to lightning receptors mounted on the blades, hub, or other wind turbine components. A common ground cable is connected to the conductors and to the wind turbine grounding system. For example, the common ground cable may be connected to a ground rod or ground rings that encircle the tower foundation. A sensor is operatively configured on the common ground cable to detect current flowing through the ground cable from a lightning strike incident on any one of the blades or hub. The sensor produces a signal proportional to the intensity of the lightning strike.

In a certain embodiment, the common ground cable passes through the foundation, and the sensor is configured on the common ground cable adjacent to the foundation. For example, the sensor may be disposed within the tower and mounted generally at the base of the tower so as to be accessible for maintenance or inspection.

The sensor may be any suitable device that generates a signal proportional to current flow through the common ground cable. For example, in one embodiment, the sensor is a current sensor, such as a conventional Rogowski coil, configured around the common ground cable that generates an output signal proportional to current flowing through the common ground cable. Desirably, the sensor produces an output signal indicative of the peak current through the common ground conductor.

Any manner of electronics may be configured to convert the signal from the Rogowski coil to a usable peak current value. For example, the coil may generate a voltage induced by the varying magnetic field over time from the current flow through the common ground conductor. An integrator circuit may be used to convert the output to a voltage corresponding to the intensity of the current flow. A peak hold circuit may be used to capture the peak output voltage from the integrator circuit. A microprocessor may be used to convert the peak voltage value to an equivalent peak current value.

The sensor (or associated electronics) may be interfaced directly with a network controller associated with a plurality of different wind turbines, for example a supervisory controller and data acquisition (SCADA) system associated with a plurality of wind turbines in a wind farm. In this embodiment, the sensor need not be interfaced with the individual wind turbine controller.

The present invention also encompasses various method embodiments for detecting current flow in a plurality of conductors within a wind turbine, wherein the plurality of conductors are connected to a common ground cable. The method may include operatively configuring a sensor on the common ground cable to detect current flowing through the common ground cable from an electrical short or a lightning strike incident on any one of combination of wind turbine components connected to the conductors.

In a particular method embodiment, a current sensor may be utilized to generate an output signal that is proportional to the intensity of the current flowing through the ground cable. This output signal may be converted to any usable signal. A hold circuit may be used to capture a peak value of the signal that is indicative of the peak current flow through the common ground cable over a defined time period or event duration. This peak value may be compared to defined values to, for example, determine the magnitude of a lightning strike or whether a physical inspection of the wind turbine components is necessary following a lightning strike on the wind turbine.

In other method embodiments, the sensor output may bypass the turbine controller and be monitored directly by a network controller, such as an SCADA system, that is common to a plurality of different wind turbines.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a perspective view of a conventional wind turbine;

FIG. 2 is a front view of a wind turbine in accordance with one embodiment of the present disclosure; and

FIG. 3 is an operational block diagram of one embodiment of a sensor and related electronics according to one embodiment of the present disclosure.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

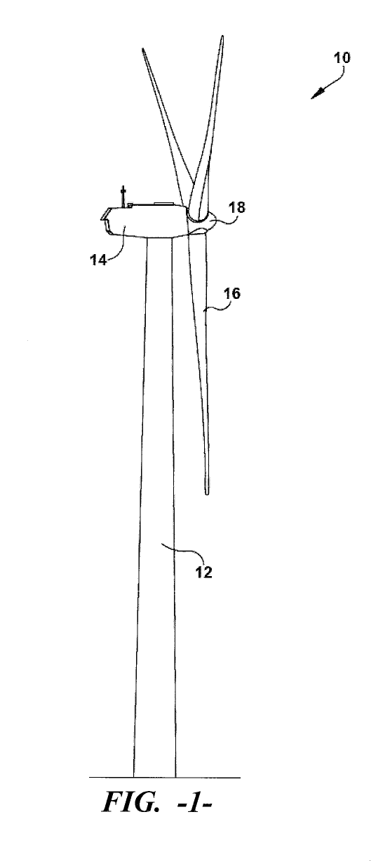

FIG. 1 illustrates a wind turbine 10 of conventional construction. The wind turbine 10 includes a tower 12 with a nacelle 14 mounted thereon. A plurality of rotor blades 16 are mounted to a rotor hub 18, such as via the roots (discussed below) of the rotor blades, which is in turn connected to a main flange that turns a main rotor shaft. The wind turbine power generation and control components are housed within the nacelle 14. The view of FIG. 1 is provided for illustrative purposes only to place the present invention in an exemplary field of use. It should be appreciated that the invention is not limited to any particular type of wind turbine configuration.

The rotor blades 16 may generally have any suitable length that enables the wind turbine 10 to function according to design criteria. For example, the rotor blades 16 may have a length ranging from about 15 meters (m) to about 91 m. The rotor blades 16 rotate the rotor hub 18 to enable kinetic energy to be transferred from the wind into usable mechanical energy, and subsequently, electrical energy. Specifically, the hub 18 may be rotatably coupled to an electric generator (not illustrated) positioned within the nacelle 14 for production of electrical energy.

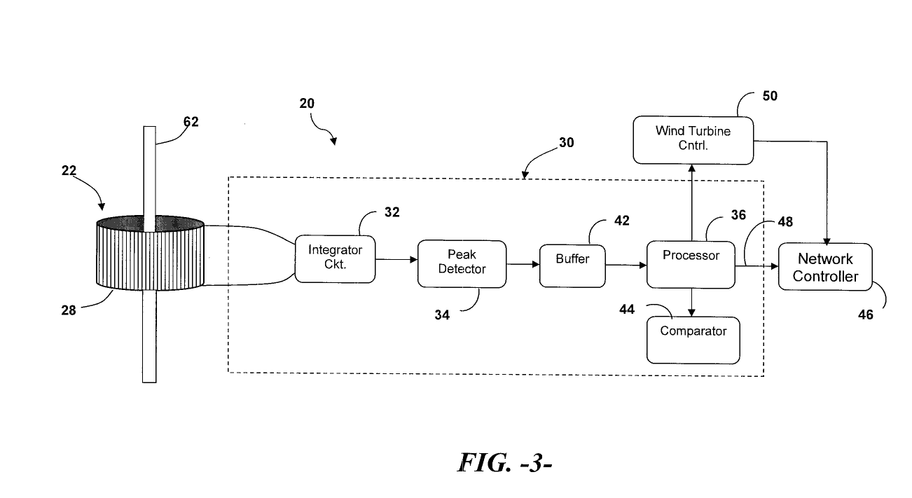

The operational functions of the wind turbine 10 are generally monitored and controlled by a wind turbine controller 50 (FIG. 3) within the nacelle 14, which may be in communication with a central site or network controller 46 (FIG. 3).

The present invention relates to a system and method for detecting current flow in a plurality of conductors within the wind turbine, wherein the plurality of conductors are connected to a common ground cable. A sensor is operatively configured on the common ground cable to detect current flowing through the common ground cable from an electrical short or a lightning strike incident on any one of combination of wind turbine components connected to the conductors.

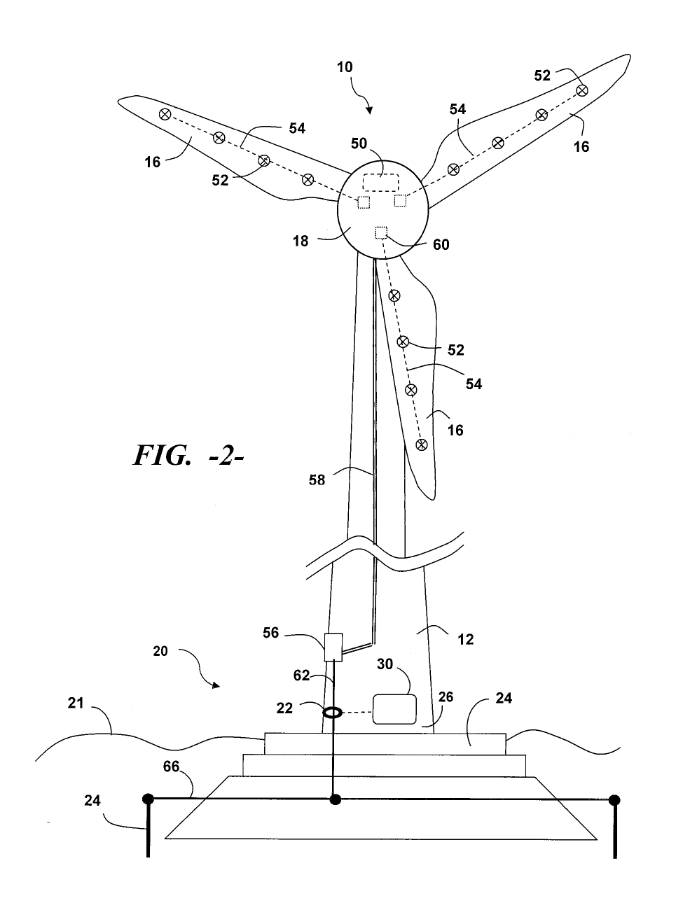

Referring to FIG. 2 in general, wind turbine 10 incorporates a grounding system 20 that may include one or more lightning receptors 52 configured along either or both of the pressure side or suction side of one or more of the blades 16. It should be understood that lightning receptors 52 may also be incorporated with the hub 18 or any other component of the wind turbine 10 that is susceptible to lightning strikes. Thus, it should be appreciated that the invention is not limited to any particular location of the lightning receptors 52 on the wind turbine 10. For example, receptors 52 may be located on the tower 12 or nacelle 14 instead of or in addition to the receptors 52 provided on the blades 16.

The lightning receptors 52 may be variously configured, and include any metal or metalized component (i.e., a metal screen, a metal rod or tip, and the like) mounted on the wind turbine components (such as on the pressure or suction sides of the blades 16) for the purpose of conducting lightning strikes to ground.

Still referring to FIG. 2, the lighting receptors 52 are electrically coupled to a conductor 54 within the respective blades 16, which may include multiple conductive components. For example, each receptor 52 may be connected by a branch line to the conductor 54, which is common to all of the receptors 52 within the blade 16. The branch line and conductor 54 have a gauge suitable for defining a conductive component of the wind turbine's overall ground system 20 for transmitting a lightning strike on any one of the receptors 52 to ground 21. The conductors 54 are electrically coupled to a respective tower conductor 58 via conventional slip ring contacts 60. Multiple tower conductors 58 may be utilized. In an alternate embodiment, a single, common tower conductor 58 may be electrically coupled to the plurality of different lightning receptors 54. The branch lines, blade conductors 54 and tower conductors 58 have a gauge suitable for defining a conductive component of the wind turbine's overall ground system 20 for transmitting a lightning strike on any one of the receptors 52 to ground 21.

It should be understood that the conductive members 54, 58 may also include any configuration of conductive blade or turbine structure within the grounding system 20, such as carbon spar caps, trailing serrations, leading edge protectors, fairings, bearings, frame structure, and so forth.

In the embodiment of FIG. 2, the tower 12 is constructed on a foundation 24, which is typically of concrete construction and may include a substantial portion that is below ground level 21. The conductors 58 are joined at a terminal or bus location 56 to a main common ground cable 62 that is disposed through the foundation 24 and electrically coupled to one or more grounding rings 66 that are formed around the base of the foundation 24. The rings 66 are typically coupled to one or more grounding rods 24.

Referring to FIGS. 2 and 3 in general, at least one current sensor 22 is configured with the common ground cable 62, desirably within the tower 12 adjacent to a base section 26 of the tower 12 so as to be readily accessible by a maintenance technician upon entry into the tower 12. This sensor 22 is uniquely configured to detect current flow through the ground cable 62 from a lightning strike incident on any one of the turbine blade or hub receptors 52 (or any other component electrically coupled to the grounding system 20). The sensor 22 is in communication with an electronics package 30 and produces a signal that is proportional to current flow through the ground cable 62, which reflects the intensity of the lightning strike.

The invention is not limited to any particular type or configuration of current sensor 22, or function and configuration of the associated electronics package 30. For example, US Patent Application Pub. No. 2009/0236853 describes a micro-electromechanical (MEMS) current sensing apparatus that may be associated with the ground cable 62 to detect and measure current flow through the cable. Semi-conductor based, magnetic field sensing systems may be utilized that employ a loop antenna, as is well-known in the art. The loop antenna detects a change in the magnetic field resulting from current flow through the cable 62, which results in a measurable voltage change at the antenna terminals.

In one embodiment, the current sensor 22 may be configured as a current transformed disposed around the ground cable 62, a secondary (step-down) transformer may be connected to the sensor 22 to step down the current produced by the sensor 22 to a usable level. This secondary transformer may be connected to a transimpedance amp that converts the current to a voltage signal that is proportional to current flow through the cable 62 (and thus to the intensity of the lightning strike). This amp may include any configuration of operational amplifiers that allow for detection of strikes above a threshold value, as well as whether the discharge is positive or negative. The gain of the transimpedance amplifier may be set by appropriate gain resistors to achieve the desired operating voltage range.

In a desirable embodiment depicted in FIG. 3, the current sensor 22 is configured as a current transformer, such as a conventional Rogowski coil 28. The operation of such devices is well-known by those skilled in the art, and need not be described in detail herein. In general, a Rogowski coil is an electrical device for measuring alternating current (AC) or high speed current pulses. It consists of a helical coil of wire with the lead from one end returning through the center of the coil to the other end, so that both terminals are at the same end of the coil. The whole assembly is then wrapped around the straight conductor (ground cable 62) whose current is to be measured. Since the voltage that is induced in the coil 28 is proportional to the rate of change (derivative) of current in the straight conductor 62, the output of the Rogowski coil 28 is usually connected to an electrical (or electronic) integrator circuit 32 to provide an output signal that is proportional to the current flow through the conductor 62.

Referring to FIG. 3, an embodiment is depicted wherein the Rogowski coil 28 (or other type of sensor 22) is configured with an electronics package 30, which may include the integrator circuit 32 as well as any other manner of signal conversion or comparison components. The package 30 may include any manner of hardware/software configuration for performing various desired functions with the processing signal generated by the sensor 22. For example, the package 30 may include a peak detector 34 that serves to record the highest voltage sensed and retain the voltage value for subsequent processing. The processing signal V(s) may be buffered by a buffer 42 and directed to a micro-processor 36 that may include various functionalities. For example, the processor 36 may be configured with a comparator 44 designed to set a bit high when the processing signal V(s) exceeds a threshold value. For example, the comparator 44 may be set to alert when a voltage is sensed corresponding to an initial 100 kA current in the ground detector, which is indicative of a lightning strike. The processor 36 may be used for any manner of further processing, such as determining and registering an actual magnitude value for the processing signal.

Magnitude determination may be accomplished via the processor 36 by comparing the processing signal to a plurality of threshold values, which define magnitude ranges. A processing signal that exceeds a given threshold value but not the next subsequent value falls within the magnitude range defined by the threshold values.

As depicted in FIG. 3, the electronics package 30 may be in communication with the wind turbine controller 50, which may in turn be in communication with a remote, central network controller 46, such as a wind farm controller or remote monitoring station controller configured as a supervisory controller and data acquisition (SCADA) system, via any manner of wired or wireless communication link 48. Alternatively, the electronics package 30 may bypass the wind turbine controller 50 and communicate directly with the central controller 48.

The grounding system 20 may include any manner of surge protection to protect the system components from excessive current spikes or to limit the maximum sensed voltage. For example, a varistor may be used to clamp to a maximum voltage, or a fuse could be used to protect the circuitry from current spikes.

The electronics package 30 may be configured to generate an alert or alarm when the processing signal exceeds the threshold value. This alert signal may be transmitted to the wind turbine generator controller 50 or directly to the network controller 46, wherein the alert may be time stamped and recorded along with the value (e.g., magnitude) of the processing signal. The alert and any other parameters or information associated with the processing signal may be used for any purpose, such as scheduling an inspection of the wind turbine generator, issuing a command to shut down the wind turbine generator, initiating a warranty claim investigation, and so forth.

It should be appreciated that the electronics package 30 may be operably configured in relatively close proximity with the current sensor 22, or remote from the current sensor 22. The components may be configured in a single integral housing unit, or in separate connected units. Any suitable configuration of the respective components for serving the functionalities discussed herein are within the scope and spirit of the invention.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A wind turbine configured with a lightning strike detection system, comprising:
a tower mounted on a ground-level foundation;
a hub mounted atop the tower, and a plurality of turbine blades configured on said hub;
a plurality of lightning strike conductors connected to any combination of said turbine blades and said hub to conduct lightning strikes to ground;
a common ground cable connected to said conductors and to a wind turbine grounding system;
a sensor operatively configured on said common ground cable to detect current flowing through said ground cable from a lightning strike incident on any one of said turbine blades or said hub, said sensor producing a signal proportional to the intensity of the lightning strike.

2. The wind turbine as in claim 1, wherein said common ground cable passes through said foundation, said sensor configured on said common ground cable adjacent to said foundation.

3. The wind turbine as in claim 2, wherein said sensor is disposed within said tower and mounted generally at a base of said tower.

4. The wind turbine as in claim 1, wherein said sensor generates a signal proportional to current flow through said common ground cable.

5. The wind turbine as in claim 4, wherein said sensor is a current sensor configured around said common ground cable that generates an output signal proportional to current flowing through said common ground cable.

6. The wind turbine as in claim 5, wherein said current sensor produces an output signal indicative of a peak current through said common ground conductor.

7. The wind turbine as in claim 6, wherein said current sensor is a Rogowski coil, and further comprising electronics that convert said output signal from said Rogowski coil to a usable peak current value.

8. The wind turbine as in claim 7, wherein said Rogowski generates a voltage induced by the varying magnetic field over time from current flow through said common ground conductor, said electronics comprising an integrator circuit that converts the output voltage to a voltage corresponding to the intensity of the current flow, a peak hold circuit that captures a peak output voltage from said integrator circuit, and a microprocessor that converts the peak voltage value to an equivalent peak current value.

9. The wind turbine as in claim 1, wherein said sensor is interfaced directly with a network controller associated with a plurality of different wind turbines.

10. The wind turbine as in claim 9, wherein said network controller is a supervisory controller and data acquisition (SCADA) system associated with a plurality of wind turbines in a wind farm.

11. The wind turbine as in claim 1, wherein said conductors are connected to lightning receptors mounted on said blades or said hub.

12. A method for detecting current flow in a plurality of conductors within a wind turbine, wherein the plurality of conductors are connected to a common ground cable, comprising:
operatively configuring a sensor on the common ground cable to detect current flowing through the common ground cable from an electrical short or a lightning strike incident on any one or combination of wind turbine components connected to the conductors.

13. The method as in claim 12, wherein the sensor is a current sensor that generates an output signal proportional to the intensity of the current flowing through the ground cable.

14. The method as in claim 13, further comprising capturing a peak value of the signal that is indicative of the peak current flow through the common ground cable over a defined time period or event duration.

15. The method as in claim 14, further comprising comparing the peak values to defined values to determine the magnitude of a lightning strike or whether a physical inspection of the wind turbine components is necessary following a lightning strike on the wind turbine.

16. The method as in claim 12, further comprising bypassing a controller associated with the wind turbine and directly interfacing the sensor with a network controller that is common to a plurality of different wind turbines.
